(19) United States
(12) Patent Application Publication
(10) Pub. No.: US 2025/0370062 A1
(43) Pub. Date: Dec. 4, 2025

(54) SYSTEM AND METHOD FOR PREDICTING BATTERY SPIKE POWER CAPABILITY

(71) Applicant: Apple Inc., Cupertino, CA (US)

(72) Inventors: Jun Hou, San Jose, CA (US); Ning Tian, San Jose, CA (US); Yangsheng Hu, San Jose, CA (US); Niankai Yang, Foster City, CA (US); Wei He, San Jose, CA (US); Nalin Chaturvedi, Union City, CA (US)

(21) Appl. No.: 18/680,787

(22) Filed: May 31, 2024

(51) Int. Cl. G01R 31/396; G01R 31/36; G01R 31/367; G01R 31/382; G01R 31/389

(52) U.S. Cl. CPC G01R 31/396; G01R 31/3648; G01R 31/367; G01R 31/382; G01R 31/389

(57) ABSTRACT

A battery system includes a battery configured to power a load, and a processing system comprising one or more processors. The processing system is configured to determine an electrical characteristic of the battery at a start of a prediction interval, predict a first predicted electrical characteristic of the battery in a first subsection of the prediction interval based at least in part on the electrical characteristic, predict a second predicted electrical characteristic of the battery in a second subsection of the prediction interval based at least in part on the electrical characteristic, the first predicted electrical characteristic, or both, and predict a spike power capability that the battery can support after an end of the prediction interval based at least in part on the second predicted electrical characteristic.

### BACKGROUND

The present disclosure relates generally to batteries, such as secondary or rechargeable batteries (e.g., lithium-ion batteries, lithium iron phosphate batteries, lithium-ion polymer batteries, nickel-cadmium batteries, nickel-metal hydride batteries, lead-acid batteries, etc.), and more specifically to predicting battery spike power capability of such batteries and future power demand of (or on) such batteries.

Batteries such as those described above may be employed in a variety of applications, such as a consumer electronic. Power drawn from the battery and applied to a load (e.g., the consumer electronic) can be highly dynamic, non-linear, and complex. In certain operating conditions, for example, the power drawn from the battery and applied to the load may spike (e.g., surge or increase in a short duration of time). If a battery spike power capability of the battery is relatively low, the battery may be incapable of supporting spike conditions. Without a robust and accurate prediction of battery spike power capability, the battery may be ill-equipped to prepare for the spike conditions, which can lead to an unexpected power off (UPO) or brownout, harming a user experience and/or leading to other negative effects associated with the battery, the load, or both. Additionally or alternatively, traditional configurations may be ill-equipped to accurately determine a future power demand of (or on) the battery. Accordingly, it is now recognized that improved systems and methods are desired.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In an embodiment, a battery system includes a battery configured to power a load and a processing system comprising one or more processors. The processing system is configured to determine an electrical characteristic of the battery at a start of a prediction interval, predict a first predicted electrical characteristic of the battery in a first subsection of the prediction interval based at least in part on the electrical characteristic, and predict a second predicted electrical characteristic of the battery in a second subsection of the prediction interval based at least in part on the electrical characteristic, the first predicted electrical characteristic, or both. The processing system is also configured to predict a spike power capability that the battery can support after an end of the prediction interval based at least in part on the second predicted electrical characteristic.

In another embodiment, one or more tangible, non-transitory, computer-readable media stores instructions thereon that, when executed by a processing system having one or more processors, are configured to cause the processing system to perform various functions. The functions include determining an electrical characteristic of a battery at a start of a prediction interval, determining (e.g., based at least in part on the electrical characteristic) a first predicted electrical characteristic of the battery in a first subsection of the prediction interval, and determining (e.g., based at least in part on the electrical characteristic, the first predicted electrical characteristic, or both) a second predicted electrical characteristic of the battery in a second subsection of the prediction interval. The functions also include determining a long-term predicted spike power capability that the battery can support after an end of the prediction interval based at least in part on the second predicted electrical characteristic.

In another embodiment, a method of mitigating a brownout or unexpected power off (UPO) of a load powered by a battery includes determining, via a processing system including one or more processors, an electrical characteristic of the battery at a start of a prediction interval. The method also includes determining, via the processing system and based at least in part on the electrical characteristic, a first predicted electrical characteristic of the battery in a first subsection of the prediction interval. The method also includes determining, via the processing system and based at least in part on the electrical characteristic, the first predicted electrical characteristic, or both, a second predicted electrical characteristic of the battery in a second subsection of the prediction interval. The method also includes determining, via the processing system, a predicted spike power capability that the battery can support at an end of the prediction interval based at least in part on at least the second predicted electrical characteristic.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a block diagram of a battery configured to power a load, such as the electronic device of FIG. 1, where the battery includes a Battery Management Unit (BMU) configured to determine a predicted battery spike power capability of the battery, a predicted power demand of (or on) the battery, or both, according to embodiments of the present disclosure;

FIG. 3 is a schematic illustration of a graph depicting a predicted battery spike power capability of a battery, such as the battery of FIG. 2, at an end of a prediction interval (e.g., preload horizon), according to embodiments of the present disclosure;

FIG. 4 is a block diagram illustrating an algorithm for determining a predicted battery spike power capability of a battery, such as the battery of FIG. 2, at an end of a prediction interval, according to embodiments of the present disclosure;

FIG. 5 is block diagram illustrating a preload current calculator employed in an algorithm, such as the algorithm of FIG. 4, for determining a predicted battery spike power capability of a battery, such as the battery of FIG. 2, according to embodiments of the present disclosure;

FIG. 6 is a block diagram illustrating a predicted battery spike power capability calculator employed in an algorithm, such as the algorithm of FIG. 4, according to embodiments of the present disclosure;

FIG. 7 is a block diagram illustrating a model error correction calculator employed in an algorithm, such as the algorithm of FIG. 4, for determining a predicted battery spike power capability of a battery, such as the battery of FIG. 2, according to embodiments of the present disclosure;

FIG. 8 is a schematic illustration of a graph depicting a virtual voltage residual determined by a model error correction calculator, such as the model error correction calculator of FIG. 7, according to embodiments of the present disclosure;

FIG. 9 is a block diagram illustrating a system configured to determine a predicted power demand of (or on) a battery, such as the battery of FIG. 2, according to embodiments of the present disclosure;

FIG. 10 is a schematic illustration of a graph depicting a power demand curve over an observation interval and a prediction interval, according to embodiments of the present disclosure; and

FIG. 11 is a process flow diagram illustrating a method of controlling a battery, such as the battery of FIG. 2, or a load, such as the electronic device of FIG. 1, based on a predicted battery spike power capability of the battery and a predicted power demand on (or of) the battery, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on).

This disclosure is directed to batteries, such as secondary or rechargeable batteries (e.g., lithium-ion batteries, lithium iron phosphate batteries, lithium-ion polymer batteries, nickel-cadmium batteries, nickel-metal hydride batteries, lead-acid batteries, etc.), employed in a variety of applications, such as a consumer electronic. More specifically, the present disclosure is directed to embodiments of systems and methods for determining a predicted battery spike power capability of such batteries in a long future (e.g., 10 seconds or more in advance, such as up to 4 or 5 minutes in advance), for determining a predicted power demand of (or on) such batteries, or both, as described in detail below.

Power drawn from a battery and applied to a load (e.g., a consumer electronic) can be highly dynamic, non-linear, and complex (e.g., based on time-variable and/or non-linear dynamics or characteristics, such as impedance and open-circuit voltage or OCV). In certain operating conditions, for example, the power drawn from the battery and applied to the load may spike (e.g., surge or increase in a short duration of time), which can pose a risk of unexpected power off and/or brownout. In accordance with the present disclosure, the battery may include, among other componentry, a battery management unit (BMU), sometimes referred to as a battery management system (BMS), having componentry (e.g., processing circuitry, memory circuitry, sensors, etc.) configured to monitor operational aspects of the battery and/or the load in an effort to reduce the risk of unexpected power off and/or brownout. For example, the BMU may be configured to determine a predicted battery spike power capability of the battery in a long future (e.g., 10 seconds or more in advance, such as up to 4 or 5 minutes in advance). That is, the BMU may predict at a certain point in time what the battery spike power capability of the battery will be in the long future.

The BMU may determine the predicted battery spike power capability based on one or more electrical characteristic(s) (e.g., detected electrical characteristic, measured electrical characteristic, actual electrical characteristic) of the battery at a start of a prediction interval (e.g., a preload horizon), and based on various iterative processing steps employed in an algorithm for corresponding prediction interval subsections over the prediction interval. That is, various iterations of the algorithm may correspond to various prediction interval subsections over the prediction interval. The iterative processing steps may be employed to accommodate time-variable and/or non-linear electrical characteristics of the battery, as previously described. For example, while such time-variable and/or non-linear electrical characteristics of the battery may be assumed constant or linear over a relatively short time period (e.g., a short future, such as less than 10 seconds), such time-variable and/or non-linear electrical characteristics of the battery cannot be assumed constant or linear over a relatively long time period. As an example, an impedance of the battery can change significantly (e.g., increase significantly) as a state-of-charge (i.e., SOC) of the battery changes (e.g., decreases). Other characteristics that may be time-variable and/or non-linear include open-circuit voltage (i.e., OCV). For these and other reasons, the iterative processing steps of the algorithm(s) in the present disclosure, whereby the prediction interval is segmented into a number of prediction interval subsections, better accommodates for the time-variable and/or non-linear electrical characteristics of the battery in determining a predicted battery spike power capability over a relatively long prediction interval (e.g., 10 seconds or more in advance, such as up to 4 or 5 minutes in advance), or “long future.”

For example, the BMU may determine (e.g., measure, detect, and/or infer) one or more initial electrical characteristic(s) of the battery at a start of the prediction interval. Further, the BMU may determine one or more first predicted electrical characteristic(s) of the battery corresponding to a first prediction interval subsection of the prediction interval based at least in part on the initial electrical characteristic(s), determine one or more second predicted electrical characteristic(s) of the battery corresponding to a second prediction interval subsection of the prediction interval based at least in part on the initial electrical characteristic(s), the first predicted electrical characteristic(s), or both, determine one or more third predicted electrical characteristic(s) of the battery corresponding to a third prediction interval subsection of the prediction interval based at least in part on the initial electrical characteristic(s), the first predicted electrical characteristic(s), the second predicted electrical characteristic(s), or a combination thereof, and so on and so forth. In some embodiments, a battery model (e.g., enabled via a resistor-capacitor or RC circuit) may be used in one or more steps at each iteration of the algorithm to determine various ones of the electrical characteristic(s) described above. That is, the battery model may be employed to determine one or more electrical characteristic(s) at each prediction interval subsection of the prediction interval.

One or more final predicted electrical characteristic(s), such as the one or more third electrical characteristic(s) described above, in a final prediction interval subsection of the prediction interval, along with other possible inputs, may be employed to determine the predicted battery spike power capability (e.g., at or during a time period beginning with the end of the prediction interval). In this way, the time-variable and/or non-linear electrical characteristics of the battery are accounted for in determining the predicted battery spike power capability, unlike certain traditional configurations. Presently disclosed embodiments may also include a model error correction calculator that identifies one or more deviation(s) in the variable(s) employed in the battery model and/or other aspects of the algorithm, such as voltage dynamics, such that the algorithm accounts for such deviation(s) in determining the predicted battery spike power capability. In particular, the model error correction calculator corrects for errors (e.g., between predicted voltage dynamics and measured or detected voltages) that would otherwise propagate in inputs to calculations of a preload current calculator and a power capability calculator of the algorithm, described in greater detail with reference to the drawings.

By employing the iterative techniques summarized above and outlined in greater detail below with reference to the drawings, the BMU can determine with relatively strong accuracy the predicted battery spike power capability relatively far in advance (e.g., 10 seconds or more in advance, such as up to 4 or 5 minutes in advance). Further, the BMU may be configured to prepare the battery and/or the load for protection against negative effects, such as unexpected power off and/or brownout, associated with the predicted battery spike power capability being relatively low, such as less than a threshold amount. In some embodiments, the BMU may determine a predicted power demand of (or on) the battery based, for example, on historical data (e.g., historical power draw and/or battery usage data), where the predicted power demand corresponds to (or is employed to determine) the threshold amount referenced above and against which the predicted battery spike power capability is compared. In some embodiments, the BMU may perform power saving measures in response to determining that the predicted battery spike power capability is less than the threshold amount, such as initiating a low power mode and/or signaling to the load that power saving measures at the load are needed, thereby enabling a reduction in power drawn from the battery.

As described above, and in greater detail below with reference to the drawings, presently disclosed embodiments include embodiments of systems and methods for determining a predicted battery spike power capability relatively accurately and relatively far in advance, determining a predicted power demand of (or on) the battery relatively accurately and relatively far in advance, or both, thereby enabling a sufficient time margin for protecting against negative effects, such as unexpected power off and/or brownout. The above-described features, and other features of the present disclosure, may improve battery operational efficiency and a user experience, reduce a likelihood of unexpected power off and/or brownout, contribute to other technical benefits over traditional configurations, or any combination thereof. These and other aspects of the present disclosure are described in greater detail below with reference to the drawings.

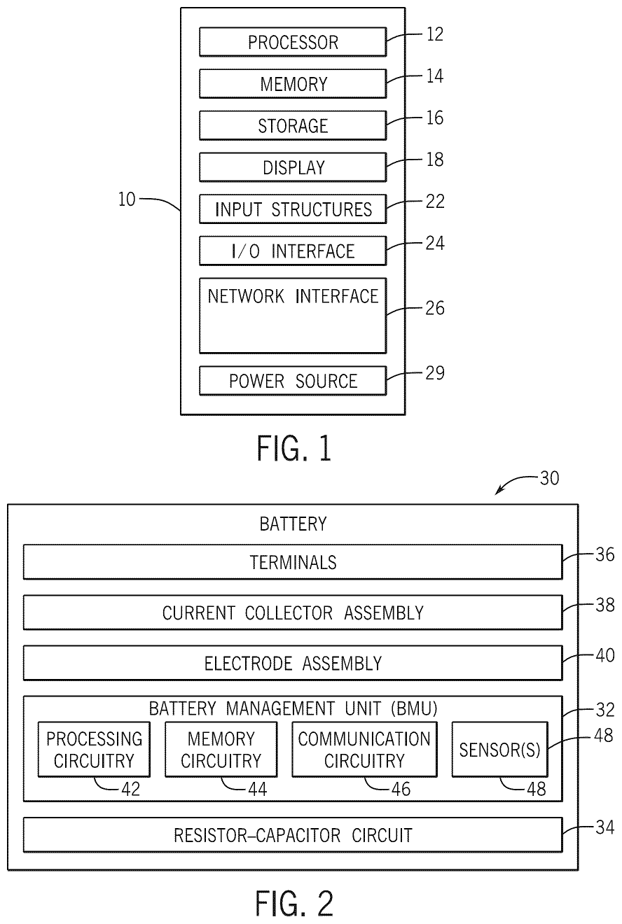

Continuing now with the drawings, FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. It should be noted that FIG. 1 is merely one example of a particular implementation and is intended to illustrate the types of components that may be present in the electronic device 10.

By way of example, the electronic device 10 may include any suitable computing device, including a desktop or notebook computer, a portable electronic or handheld electronic device such as a wireless electronic device or smartphone, a tablet, a wearable electronic device, and other similar devices. In additional or alternative embodiments, the electronic device 10 may include an access point, such as a base station, a router (e.g., a wireless or Wi-Fi router), a hub, a switch, and so on. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector, a universal serial bus (USB), or other similar connector and protocol. The network interface 26 may include, for example, one or more interfaces for a personal area network (PAN), such as an ultra-wideband (UWB) or a BLUETOOTH® network, a local area network (LAN) or wireless local area network (WLAN), such as a network employing one of the IEEE 802.11x family of protocols (e.g., WI-FI®), and/or a wide area network (WAN), such as any standards related to the Third Generation Partnership Project (3GPP), including, for example, a 3rd generation (3G) cellular network, universal mobile telecommunication system (UMTS), 4th generation (4G) cellular network, Long Term Evolution® (LTE) cellular network, Long Term Evolution License Assisted Access (LTE-LAA) cellular network, 5th generation (5G) cellular network, and/or New Radio (NR) cellular network, a 6th generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, and so forth.

The power source 29 of the electronic device 10 may include any suitable source of power, such as a rechargeable lithium polymer (Li-poly) battery and/or an alternating current (AC) power converter. In accordance with embodiments of the present disclosure, a battery of the power source 29 may include componentry configured to determine a predicted battery spike power capability over a long future (e.g., 10 seconds or more in advance, such as up to 4 or 5 minutes in advance), thereby enabling the battery to prepare against unexpected power off and/or brownout risk. Further, the battery may include componentry configured to determine a predicted future power demand of (or on) the battery. The predicted battery spike power capability, the predicted future power demand, or both may be employed to protect against and/or reduce a likelihood of unexpected power off and brownout, thereby improving a user experience and reducing a likelihood of negative effects on the electronic device 10, including but not limited to the battery. These and other aspects of the present disclosure are described in detail below with reference to later drawings.

FIG. 2 is a block diagram of an embodiment of a battery 30 configured to power a load, such as the electronic device 10 of FIG. 1, where the battery 30 includes a Battery Management Unit (BMU) 32 configured to determine a predicted battery spike power capability of the battery 30, configured to determine a predicted power demand of (or on) the battery 30, or both. The battery 30 may correspond to, or form a portion of, the power source 29 of the electronic device 10 of FIG. 1. As shown, the battery 30 may include a resistor-capacitor (RC) circuit 34 employed in a battery model or equivalent model circuit, which may be used in a process to determine, for example, the predicted battery spike power capability of the battery 30. The battery 30 also includes terminals 36, a current collector assembly 38 coupled to the terminals 36, and an electrode assembly 40 coupled to the current collector assembly 38, among other possible features. The terminals 36, the current collector assembly 38, and the electrode assembly 40 may be electrically connected such that power is deliverable by the battery 30 to a load (e.g., the electronic device 10 of FIG. 1). In some embodiments, the above-described componentry may be disposed within an enclosure of the battery 30, although certain componentry (e.g., the BMU 32 or a portion thereof) may be disposed along an exterior of the enclosure.

As shown, the BMU 32 includes processing circuitry 42 (e.g., one or more processors), memory circuitry 44 (e.g., one or more memories), communication circuitry 46 (e.g., one or more transmitters, receivers, and/or transceivers), and one or more sensors 48. While the sensor(s) 48 are illustrated as a part of the BMU 32 in FIG. 2, the sensor(s) 48 may be separate from and communicatively coupled with the BMU 32. Likewise, the RC circuit 34 may be separate from and communicatively coupled to the BMU 32, or the RC circuit 34 may form a part of the BMU 32. In accordance with the present disclosure, the sensor(s) 48 may be configured to detect one or more electrical characteristic(s), referred to in certain instances of the present disclosure as one or more initial electrical characteristic(s), of the battery 30. Such initial electrical characteristic(s) may include, for example, a battery voltage, a battery current, a battery temperature, a state-of-charge (SOC), some other detectable or measurable electrical characteristic, or any combination thereof.

The processing circuitry 42 is configured to execute instructions stored in the memory circuitry 44 to perform various functions, such as executing an algorithm configured to determine the predicted battery spike power capability of the battery 30 at an end of a prediction interval and based at least in part on sensor data received from the sensor(s) 48. In some embodiments, the RC circuit 34 may be employed to model or facilitate modeling of various electrical characteristics of the battery 30. For example, detectable variables and/or outputs of the RC circuit 34 may be employed in a battery model to predict various electrical characteristics of the battery 30. An example of the RC circuit 34 and corresponding battery model, employed to model various electrical characteristics of the battery 30, can be found in U.S. Pat. No. 10,830,821 to Lou et al., issued Nov. 10, 2020, which is incorporated by reference herein.

In general, certain embodiments of the RC circuit 34 may be employed to determine transient voltage response, or current response, of the battery 30 to pulsed currents or voltages, and/or any other suitable time varying signals. In some embodiments, the model representation corresponds to an open circuit voltage of the battery 30 and series resistance of the battery 30. A learning cycle may be employed (e.g., via the BMU 32) to determine various RC parameters (e.g., variables, electrical characteristics, or outputs) of the RC circuit 34, whereby the RC parameters are used in an algorithm for determining the predicted battery spike power capability of the battery 30 over a long future, as described in detail below. Thus, the battery model may include software logic and/or hardware logic configured to model certain electrical characteristics (e.g., unknown characteristics) of the battery 30, such as certain future electrical characteristics, based on certain other electrical characteristics (e.g., known characteristics) of the battery 30, such as certain current, measured, and/or detected electrical characteristics. In this way, as described in detail below, the BMU 32 may determine the predicted battery spike power capability in the long future (e.g., 10 seconds or more in advance, such as up to 4 or 5 minutes in advance), among other possible battery characteristics.

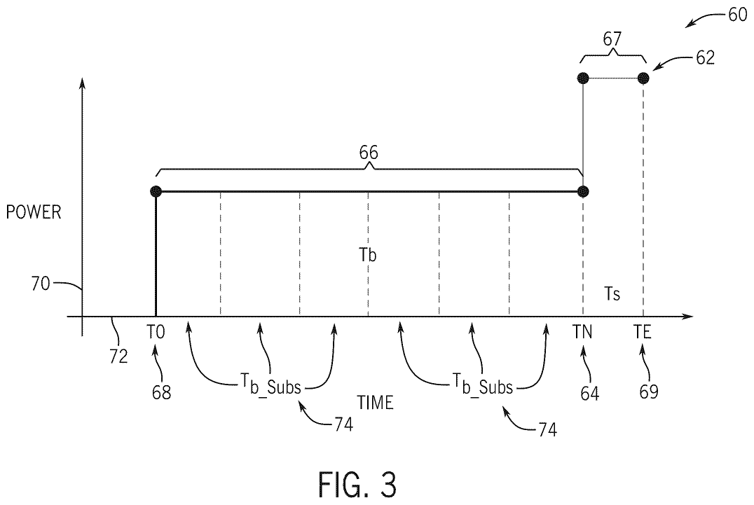

FIG. 3 is a schematic illustration of an embodiment of a graph 60 depicting a predicted battery spike power capability 62 of a battery, such as the battery 30 of FIG. 2, after an end 64 (i.e., T_{N}) of a prediction interval 66 (i.e., T_{b}). That is, the predicted battery spike power capability 62 is determined for a battery spike power interval 67 (i.e., T_{S}), which occurs between the end 64 of the prediction interval 66 and an end 69 (i.e., T_{E}) of the battery spike power interval 67. The prediction interval 66 may be referred to in certain instances of the present disclosure as a preload horizon.

The processing circuitry 42 of the BMU 32 in FIG. 2 may execute an algorithm at a start 68 (i.e., T₀) of the prediction interval 66 in FIG. 3 based at least in part on the sensor data received from the sensor(s) 48 in FIG. 2, where the sensor data is indicative of the initial electrical characteristic(s) detected by the sensor(s) 48 at or immediately adjacent in time to the start 68 of the prediction interval 66. The sensor data may be indicative of a battery state-of-charge (SOC), a battery temperature, a battery voltage, a battery current, a battery impedance, and/or a battery age, among other possible characteristics. As shown, the graph 60 in FIG. 3 depicts power 70 (i.e., a product of battery voltage and battery current), such as predicted power, against time 72 (i.e., future time). While the prediction interval 66 in FIG. 3 illustrates the power 70 as constant through the prediction interval 66, it should be understood that the power 70 and/or other electrical characteristics (e.g., predicated electrical characteristics) may vary over the prediction interval 66. For example, as described in detail below with reference to later drawings, the prediction interval 66 may be broken into various prediction interval subsections 74 (i.e., T_{b_subs}), where processing steps of a first prediction interval subsection may rely at least in part on the sensor data described above, and processing steps of each subsequent prediction interval subsection may rely at least in part on a predicted electrical characteristic of the immediately preceding prediction interval subsection.

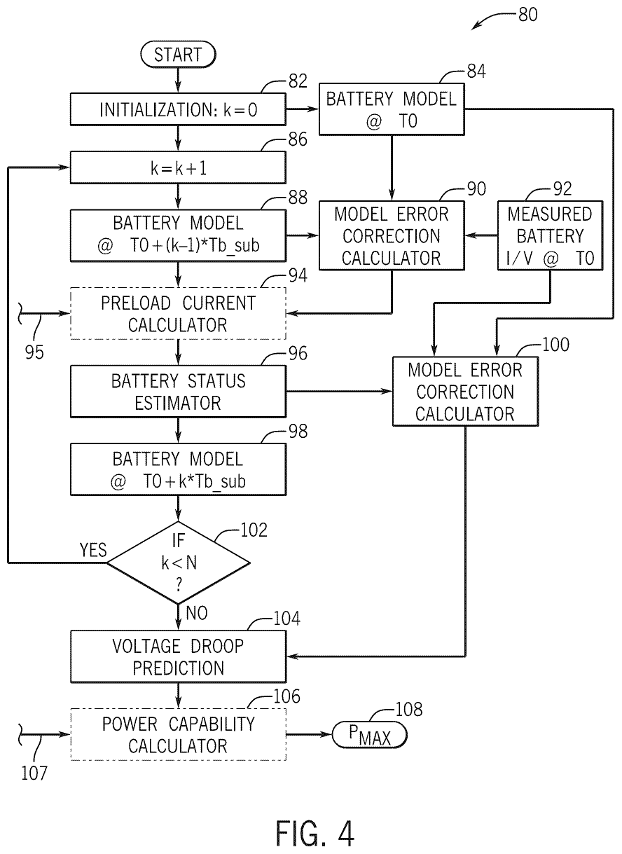

For example, FIG. 4 is a process flow diagram illustrating an embodiment of an algorithm 80 for determining a predicted battery spike power capability of a battery, such as the battery 30 of FIG. 2, over the battery spike power interval 67 beginning with the end 64 of the prediction interval 66 illustrated in FIG. 3. In the embodiment illustrated in FIG. 4, the algorithm 80 begins with an initialization step 82 at which k is set to zero for Tₖ, where Tₖ is indicative of a time instance or prediction interval subsection in the prediction interval. The algorithm 80 also includes, at step 84, executing a battery model at T₀ (e.g., by way of the RC circuit 34 in FIG. 2) to determine various electrical characteristics, such as voltage dynamics, employed in later steps of the algorithm 80. As previously described, an example of the battery model can be found in U.S. Pat. No. 10,830,821 to Lou et al., issued Nov. 10, 2020, which is incorporated by reference herein. One or more input(s) to the battery model may include, for example, a battery temperature, a battery state-of-charge (i.e., SOC), and/or battery age at T₀ in certain embodiments. In certain other embodiments, the inputs may additionally or alternatively include a battery voltage and/or a battery current at T₀. As previously described, and as described in greater detail below, the battery model may be configured to produce certain predicted electrical characteristics, such as voltage dynamics, based on these input(s).

The algorithm 80 also includes proceeding, at step 86, to the next time instance and/or prediction interval subsection of the prediction interval (i.e., by adding one to k, as shown). The algorithm 80 also includes employing, at step 88, the battery model described above with respect to step 84, but at T_{0+(k-1)*Tb_sub} instead of T₀, where T_{b_sub} corresponds to a prediction subsection interval of the prediction interval, as previously described. In the first pass of the algorithm 80, the output(s) from the battery model at step 84 may be similar to the output(s) from the battery model at step 88. However, in subsequent passes of the algorithm 80 (e.g., when the algorithm 80 returns to step 86 based on the decision at step 102, described in greater detail below), the output(s) from the battery model at step 88 may be substantially different than the output(s) from the battery model at step 84.

Variables from the battery model at step 84 and at step 88, such as variables indicative of voltage dynamics, are transmitted to a model error correction calculator at step 90 of the algorithm 80. The model error correction calculator at step 90 also receives one or more input(s) indicative of, for example, detected or measured battery current and/or detected or measured battery voltage at T₀. In general, the model error correction calculator accounts for variations in these variables and/or inputs at or between various steps of the algorithm 80, such as between steps 84 and 88. As an example, the model error correction calculator may identify a deviation between a measured or detected voltage and predicted voltage dynamics from one or more battery models. In doing so, certain model errors are accounted for such that they do not propagate in inputs to calculations carried out by a preload current calculator employed at step 94 of the algorithm 80 and/or by a power capability predictor (referred to in certain instances of the present disclosure as a battery spike power capability calculator) at step 106 of the algorithm 80, as described in greater detail below.

The algorithm 80 also includes receiving, at step 94, the outputs (e.g., indicative of voltage dynamics) from the battery model at step 88 at a preload current calculator, referred to in certain instances of the present disclosure as a current demand calculator. The preload current calculator also receives an input from the model error correction calculator employed at step 90, as shown in FIG. 4 and described in greater detail with reference to later drawings. The preload current calculator at step 94 may also receive one or more additional input(s) 95 indicative of an estimated future power demand and/or a future power demand horizon and its subsection. While the preload current calculator is described in greater detail with reference to later drawings, in general, the preload current calculator outputs a preload current (referred to in certain instances of the present disclosure as a current demand, a predicted current demand, or a predicted preload current), such as an estimated preload current, corresponding to T_{0+k*Tb_sub}.

The algorithm 80 in the illustrated embodiment then continues to step 96, where a battery status is estimated for T_{0+k*Tb_sub} based at least in part on the preload current output from the preload current calculator at step 94. While the battery status may correspond to a state of charge (i.e., SOC) of the battery in certain embodiments, in other embodiments, the battery status may correspond to a battery temperature and/or a battery age. The algorithm 80 in the illustrated embodiment continues to step 98, where another instance of the battery model is employed for T_{0+k*Tb_sub}. The battery model at step 98 receives one or more input(s) corresponding to the battery status (e.g., SOC, battery temperature, and/or battery age) determined via the battery status estimator at step 96 described above. Variables from the battery model at step 98 are also received by another instance of the model error correction calculator at step 100, along with the output(s) from the battery model at step 84 and the battery current and battery voltage characteristics detected at step 92. Based on this data, the model error correction calculator employed at step 100 accounts and corrects for deviations in the variables and/or inputs at or between various steps of the algorithm 80, such as between steps 84 and 88, which is used to ensure that such errors do not propagate in inputs to a power capability predictor (or calculator) employed at step 104 of the algorithm 80, as previously described. Such errors may be identified, for example, based on deviations between predicted voltage dynamics and measured or detected voltages. The model error correction calculator employed at step 100 is described in greater detail with reference to later drawings.

The algorithm 80 may then proceed to step 102, where k is compared against N, N being equal to the total number of prediction interval subsections in the prediction interval. If k is less than N, the algorithm 80 proceeds back to step 86, where steps 86 through 100 are performed again for the next time instance or prediction interval subsection of the prediction interval. In this way, electrical characteristics of the battery in a preceding prediction interval subsection of the prediction interval influence the determination of electrical characteristics (e.g., predicted electrical characteristics) of the battery in a subsequent prediction interval subsection of the prediction interval. Once k is not less than N at step 102 (e.g., k is equal to N, or after all prediction interval subsections of the prediction interval have been considered), the algorithm 80 proceeds to step 104. At step 104, the algorithm 80 includes determining a predicted voltage droop T_{0+k*Tb_sub} based on the output(s) (e.g., voltage dynamics) from the battery model executed at step 98 in the last iteration of the algorithm 80. For example, the output from step 104 may include voltage at T_{0+N+Tb_sub}. Such output is received by a power capability predictor at step 106 of the algorithm 80.

In some embodiments, the power capability predictor also receives one or more additional input(s) 107, such as a cutoff voltage (i.e., V_{cut}), the battery spike power interval 67 (i.e., Tₛ, or amount of time) of FIG. 3, or related information. The cutoff voltage, for example, is the voltage at which the battery is considered fully discharged, beyond which further discharge is undesirable. The power capability predictor at step 106 may determine a maximum current (i.e., Iₘₐₓ) and/or determine, based on Iₘₐₓ, the predicted battery spike power capability (i.e., Pₘₐₓ), where Pₘₐₓ may be equal to the product of Iₘₐₓ and the cutoff voltage (i.e., V_{cut}). Pₘₐₓ, illustrated at step 108 of the algorithm 80, may be the final output of the algorithm 80 and indicative of the predicted battery spike power capability at the end of the prediction interval and over the battery spike power interval.

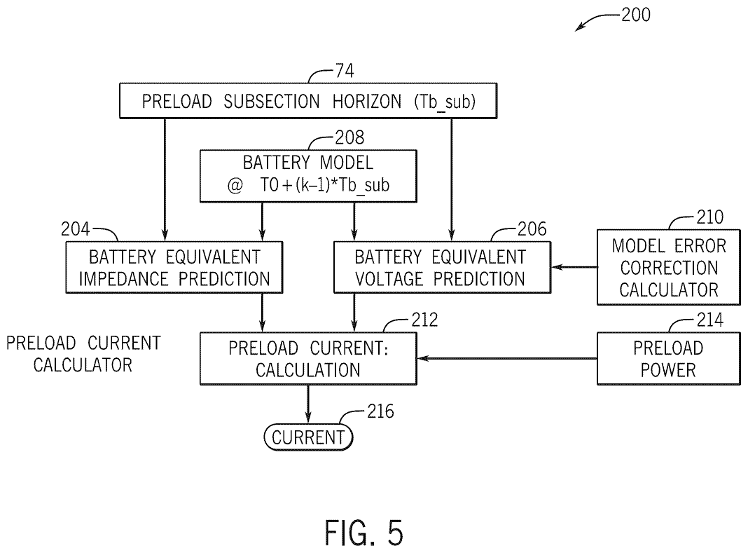

As previously described, the iterative approach employed in the algorithm 80 of FIG. 4 accommodates and accounts for time-variable and/or non-linear electrical characteristics of a battery, such as the battery 30 in FIG. 2, which may vary between the prediction interval subsections of the prediction interval. For example, while such time-variable and/or non-linear electrical characteristics of the battery 30 in FIG. 2 may be assumed constant and/or linear over a relatively short time period, such time-variable and/or non-linear electrical characteristics of the battery cannot be assumed constant and/or linear over a relatively long time period. A battery impedance, for example, can change significantly (e.g., increase significantly) as a batter SOC changes (e.g., decreases). Other characteristics that may be time-variable and/or non-linear include open-circuit voltage (i.e., OCV). For these and other reasons, the iterative processing steps in the algorithm 80 of FIG. 4, whereby the prediction interval is segmented into a number of prediction interval subsections, better accommodates and accounts for the time-variable and/or non-linear electrical characteristics in determining the predicted battery spike power capability over a relatively long prediction interval (e.g., 10 seconds or more in advance, such as up to 4 or 5 minutes in advance), or “long future.” As previously described, the algorithm 80 employs the preload current calculator at step 94, the model error correction calculator at steps 90 and 100, and the power capability estimator (or calculator) at step 106. Each of these calculators is elaborated upon below with reference to FIGS. 5-8.

FIG. 5 is block diagram illustrating an embodiment of a preload current calculator 200 (or future current demand calculator) employed in an algorithm, such as at step 94 of the algorithm 80 of FIG. 4, for determining a predicted battery spike power capability of a battery, such as the battery 30 of FIG. 2. In the illustrated embodiment, the preload current calculator 200 determines, for a particular prediction interval subsection 74 (i.e., T_{b_sub}), a battery equivalent impedance prediction 204 and a battery equivalent voltage prediction 206. The battery equivalent impedance prediction 204 and the battery equivalent voltage prediction 206 may be based at least in part on a battery model 208 at T_{0+(k-1)*Tb_sub} (e.g., output(s) from the battery model 208, such as voltage dynamics), employed at step 88 in the algorithm 80 of FIG. 4. Further, the battery equivalent voltage prediction 206 may be based at least in part on an output from a model error correction calculator 210, which is described in greater detail with reference to later drawings. The preload current calculator 200 determines a preload current calculation 212 based at least in part on the battery equivalent impedance prediction 204, the battery equivalent voltage prediction 206, and at least one input indicative of preload power 214 (e.g., estimated future power demand). The preload current calculation 212 outputs a preload current 216 corresponding to the prediction interval subsection of the prediction interval, as previously described.

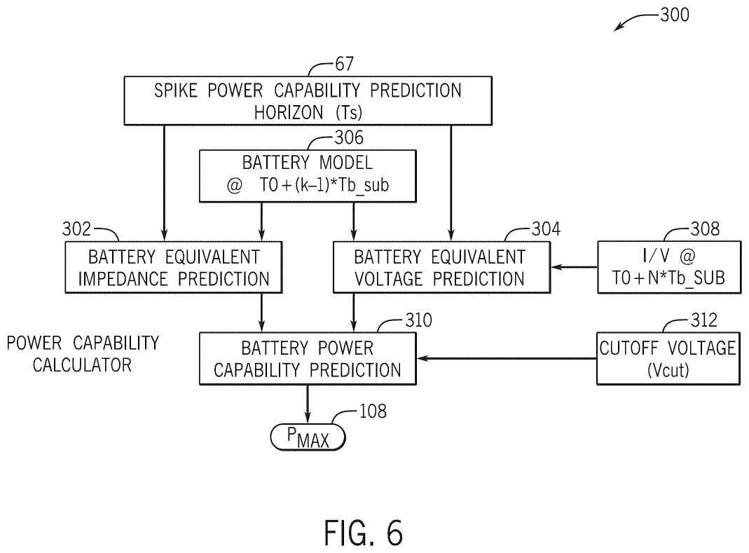

FIG. 6 is a bock diagram illustrating an embodiment of a predicted battery spike power capability calculator 300 employed in an algorithm, such as at step 106 of the algorithm 80 in FIG. 4. In the illustrated embodiment, the predicted battery spike power capability calculator 300 determines a battery equivalent impedance prediction 302 and a battery equivalent voltage prediction 304 corresponding to the battery spike power interval 67 previously described with respect to FIG. 3. The battery equivalent impedance prediction 302 and the battery equivalent voltage prediction 304 may be based at least in part on outputs (e.g., indicative of voltage dynamics) from a battery model 306 executed at T_{0+k*Tb_sub}, such as T_{0+N*Tb_sub}, employed at step 98 of the algorithm 80 in FIG. 4. Further, the battery equivalent voltage prediction 304 may be based at least in part on an input 308 indicative of battery current and/or battery voltage (e.g., measured or detected battery current and/or battery voltage). The predicted battery spike power capability calculator 300 also executes, in the illustrated embodiment, a battery spike power capability prediction 310 to determine the predicted battery spike power capability (i.e., corresponding to the step 108 in the algorithm 80 of FIG. 4), or Pₘₐₓ, based at least in part on the battery equivalent impedance prediction 302, the battery equivalent voltage prediction 304, and cutoff voltage 312 (i.e., V_{cut}).

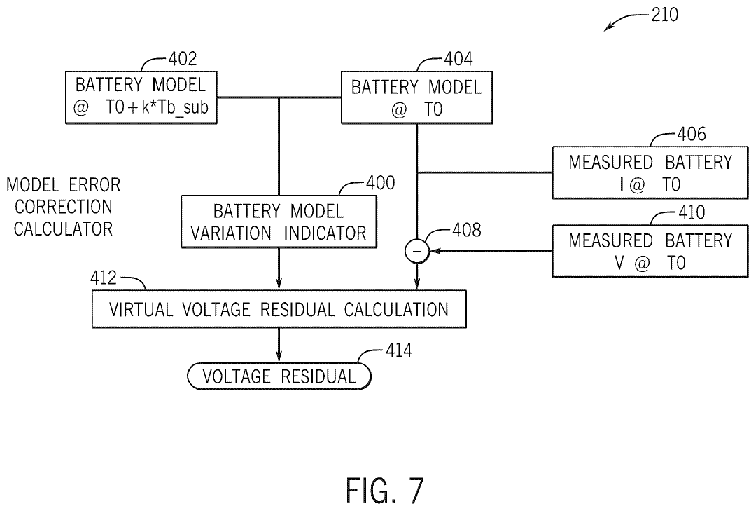

FIG. 7 is a block illustrating an embodiment of the model error correction calculator 210 employed in an algorithm, such as at steps 90 and 100 of the algorithm 80 of FIG. 4, to determine a predicted battery spike power capability of a battery, such as the battery 30 of FIG. 2. As previously described, a battery model is employed at various steps (e.g., at least steps 84, 88, and 98) in the algorithm 80 of FIG. 4. The model error correction calculator 210 may be employed to identify and correct errors at or between such battery models (e.g., between predicted voltage dynamics and measured or detected voltages). That is, the model error correction calculator 210 is employed to derive a virtual voltage residual for correcting errors that would otherwise propagate in inputs to the preload current calculator 200 of FIG. 5 (e.g., employed at step 94 in the algorithm 80 of FIG. 4), and/or in inputs to the predicted battery spike power capability calculator 300 of FIG. 6 (e.g., employed at step 106 in the algorithm 80 of FIG. 4). It should be noted that the model error correction calculator 210 in FIG. 7 is illustrated (and described below with respect to) step 100 of the algorithm 80 of FIG. 4, but that the same or similar logic may be employed in another instance of the model error correction calculator 210 with respect to step 90 of the algorithm 80 of FIG. 4.

In general, the model error correction calculator 210 may determine a deviation between a voltage prediction from one or more battery models and a measured or detected voltage, such that said deviation can be accounted for in downstream calculations. In the illustrated embodiment, the model error correction calculator 210 determines a battery model variation indicator 400, which quantifies what battery model errors may be in the future, based on variables from a battery model 402 at T_{0+k*Tb_sub} (i.e., employed at step 88 of the algorithm 80 in FIG. 4) and variables from a battery model 404 at T₀. The model error correction calculator 210 also employs a variable (e.g., output) from the battery model 404 and a detected current 406 at T₀ to determine a predicted voltage, which is compared at comparator 408 with a detected voltage 410 at T₀. A virtual voltage residual calculation 412 is executed based on the battery model variation indicator 400 and the output from the comparator 408 (e.g., a difference between predicted voltage, derived from the battery model 404 and the detected current 406, and the detected voltage 410), thereby producing a voltage residual 414.

The voltage residual 414 is employed to correct model errors such that they do not propagate to downstream calculations of the algorithm 80 in FIG. 3, as previously described. The voltage residual 414, for example, may be employed at each iteration of the iterative process in the algorithm 80 of FIG. 4. That is, the detected current 406 and the detected voltage 410 may only be detected at T₀, but the voltage residual 414 calculated based in part on the detected current 406 and the detected voltage 410 is applied at each prediction interval subsection of the prediction interval throughout the various iterations of the algorithm 80 in FIG. 4.

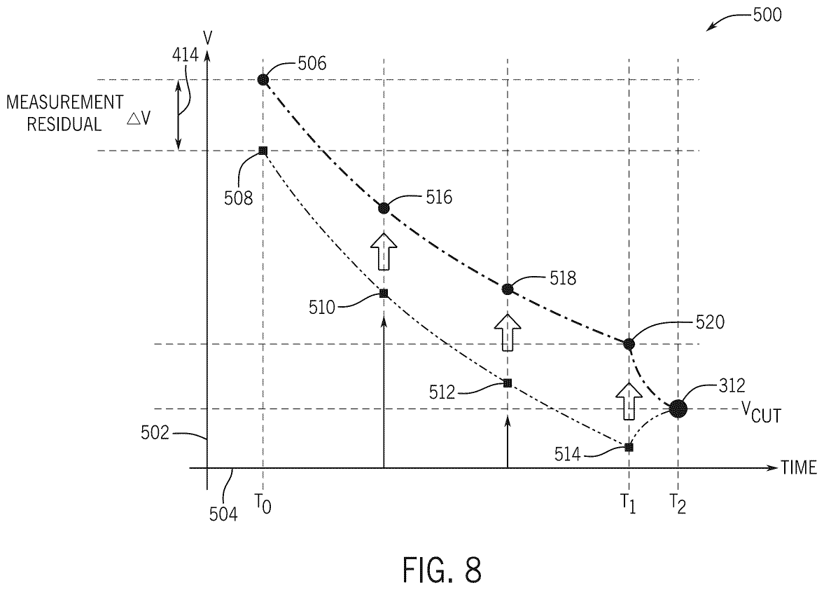

FIG. 8 is a schematic illustration of an embodiment of a graph 500 depicting a virtual voltage residual relative to a prediction interval. The graph 500 depicts voltage characteristics 502 over time 504. In the illustrated embodiment, a first data point 506 represents the detected voltage 410 at T₀ referenced above and illustrated in FIG. 7, and a second data point 508 represents a first predicted voltage (e.g., based on battery modeling). A difference between the first data point 506 and the second data point 508 corresponds to the voltage residual 414 illustrated in FIG. 7. The voltage residual 414 can be applied to subsequent predicted voltage data points 510, 512, 514 indicative of predicted voltages at future time instances (or prediction interval subsections) over the prediction interval (i.e., between T₀ and T₁), such that corrected voltage data points 516, 518, 520, respectively, are employed in downstream calculations in the algorithm 80 of FIG. 4 (e.g., with respect to a preload current calculation and/or a predicted battery spike power capability calculation). In this way, the algorithm 80 in FIG. 4 employs a relatively accurate calculation of the battery spike power capability, based at least in part on the corrected voltage data point 520 and the cutoff voltage 312 (i.e., V_{cut}) between T₁ and T₂ illustrated in FIG. 8, as previously described.

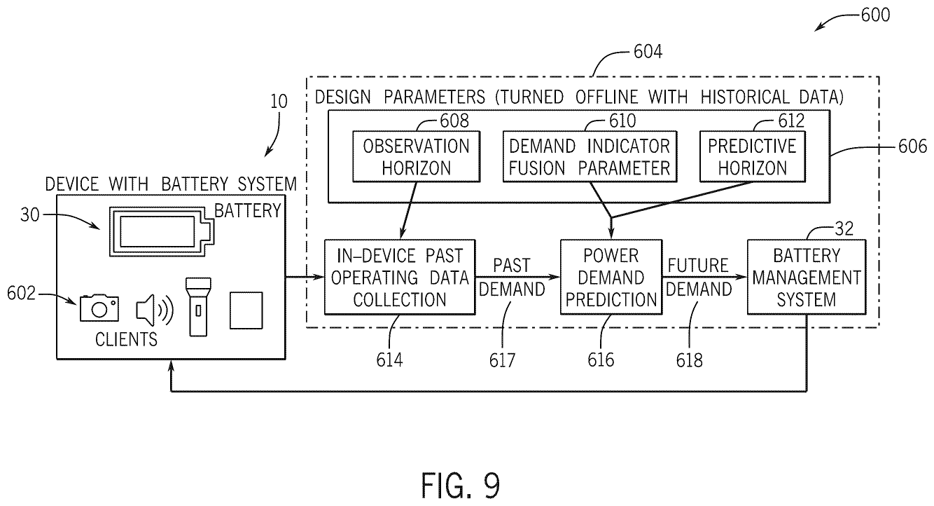

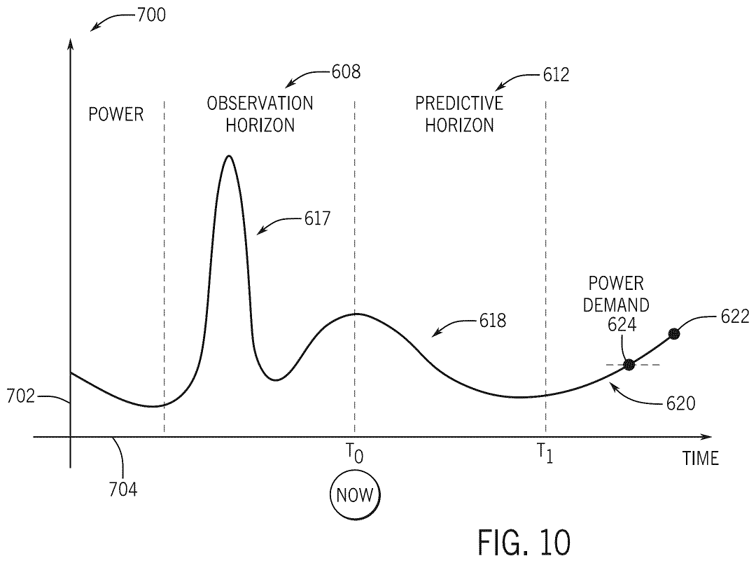

As previously described, the predicted battery spike power capability may be compared against a threshold to determine whether power saving or power consumption mitigation efforts are needed. FIGS. 9 and 10 are directed to systems and techniques for determining a predicted power demand on (or of) a battery, which may be used to determine the threshold against which the predicted battery spike power capability is compared.

For example, FIG. 9 is a block diagram illustrating an embodiment of a system 600 that employs an algorithm for determining a predicted power demand. The system 600 may include a load, such as the electronic device 10 of FIG. 1, having a power source, such as the battery 30 of FIG. 2. Various clients 602 (e.g., hardware and/or software clients) may be operated by the electronic device 10, including a camera, a microphone, a light source, software applications, etc. Operation of the clients 602 by the electronic device 10 may request power drawn from the battery 30, as previously described. Logic 604, which may be a part of the battery 30 or a part of the electronic device 10 and separate from the battery 30, and may include hardware componentry, software componentry, or both, is employed to determine the predicted power demand based on an algorithm receiving historical data associated with the electronic device 10 and/or the battery 30, as described below.

For example, design parameters 606 may include an observation interval 608 (referred to in certain instances of the present disclosure as an observation horizon), a demand indicator fusion parameter 610, and a prediction interval 612 (referred to in certain instances of the present disclosure as a prediction horizon). In some embodiments, the prediction interval 612 for determining the predicted power demand may correspond to the prediction interval 66 described with reference to earlier drawings for determining the predicted battery spike power capability. The design parameters 606 may be tuned offline with historical data. For example, in-device past operating data 614 (e.g., historical data associated with usage of the electronic device 10, historical usage of the battery 30, clients operating on the electronic device 10, or some combination thereof) may be collected over the observation interval 608. The demand indicator fusion parameter 610 is employed for producing a predicted power demand for different purposes of the BMU 32 (or BMS) of the battery 30.

A power demand prediction algorithm 616 may be executed based on past demand 617 (e.g., based on the in-device past operating data 614), and based on the demand indicator fusion parameter 610 and the prediction interval 612, to output a predicted power demand 618 in the future, which is received by the BMU 32 (or BMS) of the battery 30. For ease of illustration, the BMU 32 (or BMS) of the battery 30 is illustrated separate from the battery 30, but it should be understood that the BMU 32 (or BMS) may be integrated with the battery 30, such as within and/or along an exterior of an enclosure of the battery 30. The BMU 32 (or BMS) may compare the predicted power demand 618 in the future with the predicted battery spike power capability in an effort to determine whether power saving or power consumption mitigation techniques are desirable.

FIG. 10 is a schematic illustration of a graph 700 depicting an embodiment of a power demand curve over the observation interval 608 and the prediction interval 612. For example, the graph 700 depicts power demand 702 over time 704. The power demand curve may include several components, such as the past demand 617 (e.g., over the observation interval 608) and the predicted power demand 618 (e.g., over the prediction interval 612). In some embodiments, the power demand curve also includes a future demand component 620 after the prediction interval 612, such that future demand component 620 coincides with, as illustrated in FIG. 3, the predicted battery spike power capability 62 of the predicted battery spike power interval 67. In this way, the power demand can be compared against the predicted battery spike power capability in a common future time interval, in order to determine whether power saving or power consumption mitigation techniques are desirable. In some embodiments, a maximum future power demand value 622 of the future demand component 620 is compared against the predicted battery spike power capability, while in other embodiments, an average future power demand value 624 of the future demand component 620 is compared against the predicted battery spike power capability. Further still, in some embodiments, the future demand component 620 (e.g., the maximum future power demand value 622 or the average future power demand value 624) is employed to determine a threshold amount, which may add a safety margin (e.g., a percentage) to the value being compared against the predicted battery spike power capability.

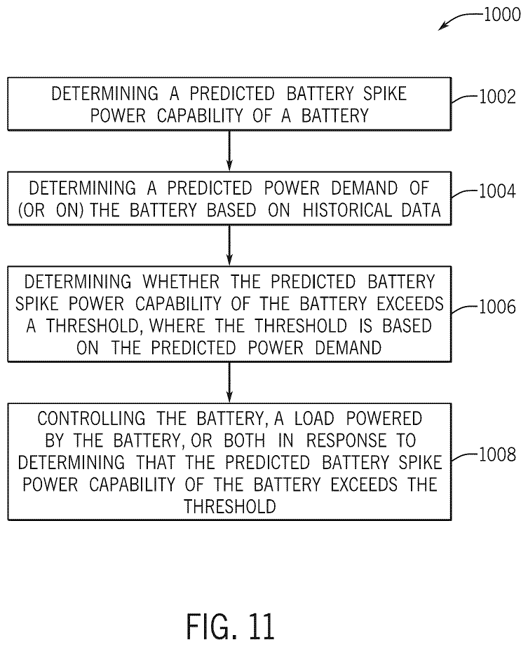

FIG. 11 is a process flow diagram illustrating an embodiment of a method 1000 of controlling a battery (e.g., the battery 30 of FIG. 2) and/or a load (e.g., the electronic device 10 of FIG. 1) based on a predicted battery spike power capability of the battery. In the illustrated embodiment, the method 1000 includes determining (block 1002) a predicted battery spike power capability of the battery. For example, an iterative approach may be employed in which a prediction interval is divided into prediction interval subsections at which various electrical characteristics are determined by an algorithm. One or more initial (e.g., detected, measured, inferred) electrical characteristic(s) may be employed at the first prediction interval subsection to determine one or more predicted electrical characteristic(s), and each subsequent prediction interval subsection may rely on the immediately preceding one or more predicted electrical characteristic(s) to determine one or more additional predicted electrical characteristic(s). The iterative approach may be employed until reaching the final prediction interval subsection, the output(s) of which are employed to determine the predicted battery spike power capability of the battery. Details regarding the algorithm and iterative approach are described above with reference to earlier drawings.

The method also includes determining (block 1004) a predicted power demand of (or on) the battery. As previously described, the predicted power demand may be determined via an algorithm that receives at least one input corresponding to historical data indicative of load (e.g., electronic device) usage or other load characteristic(s), battery usage or other battery characteristic(s), or both. Based on the at least one input, the algorithm outputs the predicted power demand of (or on) the battery, for example, at a future point in time, such as at a future point in time that coincides with the predicted battery spike power capability.

The method 1000 also includes determining (block 1006) whether the predicted battery spike power capability of the battery exceeds a threshold, where the threshold is based (e.g., at least in part) on the predicted power demand of (or on) the battery. In some embodiments, the threshold is equal to the predicted power demand. In other embodiments, the threshold is based on the predicted power demand plus a margin (e.g., a safety margin). The margin may include, for example, a percentage (e.g., 2%, 3%, 5%, or 10%) of the predicted power demand. Additionally or alternatively, the threshold may be based on the type of battery at issue, the type of load at issue, a pattern of battery and/or load usage, a combination thereof, or other considerations.

The method 1000 also includes controlling (block 1006) the battery, the load powered by the battery, or both in response to determining that the predicted battery spike power capability exceeds the threshold. For example, the control action may include a change (e.g., reduction) to a power and/or energy output of the battery, initiating a low power mode of the load or the battery, transmitting an alert, or some other measure may be controlled to reduce a risk of unexpected power off and/or brownout.

In general, presently disclosed systems, techniques, methods, algorithms, and the like, embodiments of which are described above with respect to FIGS. 1-11, improve oversight of future battery power characteristics and/or usage, reduce a risk of unexpected power off and/or brownout, improve a user experience, or any combination thereof, among other possible technical benefits over traditional configurations.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. A battery system, comprising:
a battery configured to power a load; and
a processing system comprising one or more processors, wherein the processing system is configured to:
determine an electrical characteristic of the battery at a start of a prediction interval;
predict a first predicted electrical characteristic of the battery in a first subsection of the prediction interval based at least in part on the electrical characteristic;
predict a second predicted electrical characteristic of the battery in a second subsection of the prediction interval based at least in part on the electrical characteristic, the first predicted electrical characteristic, or both; and
predict a spike power capability that the battery can support after an end of the prediction interval based at least in part on the second predicted electrical characteristic.

2. The battery system of claim 1, wherein the electrical characteristic is based at least in part on a battery state-of-charge (SOC), a battery current, a battery voltage, or a battery impedance.

3. The battery system of claim 1, wherein the first predicted electrical characteristic, the second predicted electrical characteristic, or both comprises a predicted preload current.

4. The battery system of claim 3, wherein the processing system is configured to predict the predicted preload current based at least in part on a battery equivalent impedance predication, a battery equivalent voltage prediction, and a battery preload power.

5. The battery system of claim 1, wherein the processing system is configured to predict the spike power capability by determining a product of an estimated maximum current that the battery can deliver and a battery cutoff voltage.

6. The battery system of claim 1, wherein a time interval from the start of the prediction interval to the end of the prediction interval is at least 10 seconds.

7. The battery system of claim 1, wherein the processing system is configured to execute a control action to reduce a battery draw by the load based at least in part on the spike power capability being less than a threshold amount.

8. The battery system of claim 1, wherein the processing system is configured to determine the first predicted electrical characteristic, the second predicted electrical characteristic, or both based at least in part on a voltage residual value output by a model error correction calculator that receives at least a first input indicative of a measured battery current or impedance and a second input indicative of a measured battery voltage.

9. One or more tangible, non-transitory, computer-readable media storing instructions thereon that, when executed by a processing system comprising one or more processors, are configured to cause the processing system to:
determine an electrical characteristic of a battery at a start of a prediction interval;
determine, based at least in part on the electrical characteristic, a first predicted electrical characteristic of the battery in a first subsection of the prediction interval;
determine, based at least in part on the electrical characteristic, the first predicted electrical characteristic, or both, a second predicted electrical characteristic of the battery in a second subsection of the prediction interval; and
determine a long future predicted spike power capability that the battery can support after an end of the prediction interval based at least in part on the second predicted electrical characteristic.

10. The one or more tangible, non-transitory, computer-readable media of claim 9, wherein the instructions, when executed by the processing system, are configured to cause the processing system to determine the electrical characteristic based at least in part on a battery state-of-charge (SOC), a battery current, a battery voltage, or a battery impedance.

11. The one or more tangible, non-transitory, computer-readable media of claim 9, wherein the instructions, when executed by the processing system, are configured to cause the processing system to:
determine a predicted preload current corresponding to the first predicted electrical characteristic, the second predicted electrical characteristic, or both based at least in part on a battery equivalent impedance predication, a battery equivalent voltage prediction, and a battery preload power.

12. The one or more tangible, non-transitory, computer-readable media of claim 9, wherein the instructions, when executed by the processing system, are configured to cause the processing system to determine the long future predicted spike power capability by determining a product of an estimated maximum current the battery can deliver and a battery cutoff voltage.

13. The one or more tangible, non-transitory, computer-readable media of claim 9, wherein the instructions, when executed by the processing system, are configured to cause the processing system to execute a control action to reduce a battery consumption characteristic based at least in part on the long future predicted spike power capability being less than a threshold amount.

14. The one or more tangible, non-transitory, computer-readable media of claim 9, wherein the instructions, when executed by the processing system, are configured to cause the processing system to determine the first predicted electrical characteristic, the second predicted electrical characteristic, or both based at least in part on a voltage residual value output by a model error correction calculator that receives at least a first input indicative of a measured battery current or impedance and a second input indicative of a measured battery voltage.

15. A method of mitigating a brownout or unexpected power off of a load powered by a battery, comprising:
determining, via a processing system including one or more processors, an electrical characteristic of the battery at a start of a prediction interval;
determining, via the processing system and based at least in part on the electrical characteristic, a first predicted electrical characteristic of the battery in a first subsection of the prediction interval;
determining, via the processing system and based at least in part on the electrical characteristic, the first predicted electrical characteristic, or both, a second predicted electrical characteristic of the battery in a second subsection of the prediction interval; and
determining, via the processing system, a predicted spike power capability that the battery can support at an end of the prediction interval based at least in part on at least the second predicted electrical characteristic.

16. The method of claim 15, wherein the first predicted electrical characteristic, the second predicted electrical characteristic, or both comprises a predicted preload current that is a function of a battery equivalent impedance predication, a battery equivalent voltage prediction, and a battery preload power.

17. The method of claim 15, wherein a time interval from the start of the prediction interval to the end of the prediction interval is at least 10 seconds.

18. The method of claim 15, comprising executing, via the processing system, a control action to reduce a battery consumption characteristic of the battery based at least in part on the predicted spike power capability being less than a threshold amount.

19. The method of claim 18, comprising:
determining, via the processing system and based on historical data, a predicted power demand of or on the battery; and
determining, via the processing system, the threshold amount as a function of the predicted power demand.

20. The method of claim 15, comprising determining the first predicted electrical characteristic, the second predicted electrical characteristic, or both based at least in part on a voltage residual value output by a model error correction calculator that receives at least a first input indicative of a measured battery current or impedance and a second input indicative of a measured battery voltage.
